(19) United States
(12) Patent Application Publication
(10) Pub. No.: US 2026/0043138 A1
(43) Pub. Date: Feb. 12, 2026

(54) MULTICHANNEL SHOWERHEAD FOR PROCESSING CHAMBERS

(71) Applicant: Applied Materials, Inc., Santa Clara, CA (US)

(72) Inventors: Saravjeet Singh, Sunnyvale, CA (US); Pradeep Kumar Subrahmanyan, San Jose, CA (US); Hari Kishen Ponnekanti, San Jose, CA (US); Hyeon Geu Kim, Santa Clara, CA (US); Brian Deemer, Santa Clara, CA (US); Wonjae Lee, Fremont, CA (US)

(21) Appl. No.: 19/293,902

(22) Filed: Aug. 7, 2025

Related U.S. Application Data
(60) Provisional application No. 63/682,234, filed on Aug. 12, 2024.

(51) Int. Cl. C23C 16/455; C23C 16/44

(52) U.S. Cl. CPC C23C 16/45565; C23C 16/4412; C23C 16/45561

(57) ABSTRACT

Disclosed embodiments include systems and techniques that deploy a gas showerhead having a first surface, a second surface, and a side surface. The gas showerhead includes one or more delivery channels, each delivery channel including one or more inlet ports through at least one of the first surface or the side surface, and a plurality of outlet ports through the second surface. The gas showerhead further includes an exhaust channel having a plurality of exhaust inlet ports through the second surface, and one or more exhaust outlet ports through at least one of the first surface, the second surface, or the side surface.

### RELATED APPLICATIONS

The present application claims the benefit under 35 U.S.C. § 119(e) of U.S. Provisional Ser. No. 63/682,234 filed Aug. 12, 2024, entitled “MULTICHANNEL SHOWERHEAD FOR PROCESSING CHAMBERS,” which is incorporated in its entirety by reference herein.

### TECHNICAL FIELD

This instant specification generally relates to systems and techniques that are used in electronic device manufacturing, including processing chambers. More specifically, the instant specification relates to systems and techniques for delivery of various gases and chemical substances into environments of processing chambers and evacuation of products of reactions occurring in the processing chambers.

### BACKGROUND

Manufacturing of modern materials often involves numerous processing operations, such as physical vapor deposition (PVD), chemical vapor deposition (CVD), photo-masking, etching, polishing, cleaning, and/or various other operations. In deposition, atoms of one or more selected types are delivered and attached to a substrate (e.g., a silicon wafer) held in a low or high vacuum environment inside a processing chamber. In etching, one or more reactive species are delivered to a substrate to remove portions of the substrate and/or one or more films deposited on the substrates. Materials manufactured in this manner may include monocrystals, semiconductor films, fine coatings, transistor and interconnect circuitry, and numerous other structures used in practical applications, such as electronic device manufacturing. Many of these manufacturing techniques require careful controlled delivery and evacuation of particles (atoms, ions), chemical compounds (“chemistries”) and/or other agents into or from the processing chambers. Non-uniformity of agent delivery/evacuation detrimentally affects the quality of manufacturing products.

### BRIEF DESCRIPTION OF THE DRAWINGS

The present disclosure will be understood more fully from the detailed description given below and from the accompanying drawings of various embodiments of the disclosure.

FIG. 1A illustrates an example manufacturing machine capable of deploying a multichannel showerhead with the same-side placement of delivery and exhaust ports, according to at least one embodiment.

FIG. 1B is a sectional view of a processing chamber having a multichannel showerhead with the same-side placement of delivery and exhaust ports, according to at least one embodiment.

FIG. 1C is a perspective view of another processing chamber having a multichannel showerhead with same-side placement of delivery and exhaust ports, according to at least one embodiment.

FIG. 2A-2B illustrate operations of an example processing chamber having a multichannel showerhead with same-side placement of delivery and exhaust ports, according to at least one embodiment.

FIG. 3A-3B illustrate other possible configurations of a multichannel showerhead with same-side placement of delivery and exhaust ports, according to at least one embodiment.

FIG. 4A-4I illustrate example multichannel showerheads with same-side placement of delivery and exhaust ports, according to at least one embodiment.

FIG. 5A-5B illustrate additional example multichannel showerheads with same-side placement of delivery and exhaust ports, according to at least one embodiment.

FIG. 6 is a flowchart illustrating an example method of using a multichannel showerhead with same-side placement of delivery and exhaust ports in device manufacturing, in accordance with at least one embodiment.

### SUMMARY

Disclosed herein, according to one embodiment, is a gas showerhead that includes a first surface a second surface, and a side surface. The gas showerhead further includes one or more delivery channels. Each delivery channel includes one or more inlet ports through at least one of the first surface or the side surface and a plurality of outlet ports through the second surface. The gas showerhead further includes an exhaust channel. The exhaust channel includes a plurality of exhaust inlet ports through the second surface, and one or more exhaust outlet ports through at least one of the first surface, the second surface, or the side surface.

In another embodiment, disclosed is a method that includes delivering a first gas into an environment of a processing chamber via a showerhead having a first surface, a second surface, and a side surface. The first gas interacts with a substrate located in the environment of the processing chamber. The showerhead includes a first delivery channel. The first delivery channel includes one or more first inlet ports through at least one of the first surface or the side surface, the one or more first inlet ports to intake the first gas. The first delivery channel further includes a plurality of first outlet ports through the second surface to output the first gas into the environment of the processing chamber. The showerhead includes an exhaust channel. The exhaust channel includes a plurality of exhaust inlet ports through the second surface to evacuate an exhaust gas from the environment of the processing chamber, wherein the exhaust gas comprises one or more products of an interaction of the first gas with the substrate. The exhaust channel further includes one or more exhaust outlet ports through at least one of the first surface, the second surface, or the side surface to exhaust the exhaust gas from the showerhead. The method further includes removing, via the one or more exhaust outlet ports, the exhaust gas from the showerhead.

In yet another embodiment, disclosed is a semiconductor manufacturing system that includes a processing chamber that includes a substrate and a gas showerhead having a first surface, a second surface, and a side surface. The gas showerhead further includes one or more delivery channels. Each delivery channel includes one or more inlet ports through at least one of the first surface or the side surface and a plurality of outlet ports through the second surface. The gas showerhead further includes an exhaust channel. The exhaust channel includes a plurality of exhaust inlet ports through the second surface, and one or more exhaust outlet ports through at least one of the first surface, the second surface, or the side surface.

### DETAILED DESCRIPTION

In manufacturing chambers, e.g., processing chambers, wafers or other substrates are typically held in place (e.g., using electrostatic attraction or mechanical forces) horizontally by a chuck (substrate holder) while being exposed to target atoms, ions, or other chemicals delivered to an environment of a processing chamber. The substrate can be covered by a mask that prevents access of the environment to certain regions of the substrate while exposing other regions. Chemical composition of the environment can be modified depending on a particular processing operation being performed. During deposition, the environment rich in target atoms may interact with the exposed regions to add the target atoms (e.g., atoms of nitrogen, oxygen, silicon, germanium, silicon-germanium oxide, silicon oxide, silicon nitride, etc.) to the exposed regions to form various patterned structures, unpatterned films, and/or any other target features on the substrate. During etching, plasma ions added to the environment remove exposed portions of the substrate and/or any other films/features previously deposited thereon to form a desired pattern of grooves, ridges, cavities, and/or the like, which can receive semiconducting and/or conducing materials to form transistors and/or any other circuitry (e.g., interconnect circuitry) to build a specific semiconductor device.

In conventional processing chambers, various substances are typically introduced into the environment through a showerhead positioned above the substrate. Delivery ports (nozzles) of the showerhead output a flow of a carrier gas (e.g., inert gas) carrying target substances towards the substrate. After interacting with the substrate (and/or any films or other features previously formed on the substrate), the remaining unspent target substances and various reaction by-products are removed by an exhaust system. The exhaust system is typically positioned below the substrate. For example, the carrier gas flows around the edges of the substrate before being collected by inlet ports of the exhaust system. The flow of gas around the edges has a radial component and generally results in a higher concentration of the substances near the edges compared with the middle of the substrate. These spatial variations of the concentration can lead to non-uniformities of the features formed on the substrate, which are detrimental to the device quality. Conventional solutions to the non-uniformity problem include positioning delivery nozzles in a pattern that partially compensates the non-uniformity of the flow, using nozzles of different diameters and/or angles, and/or the like. Such solutions are complex and do not fully compensate for the radial components of the carrier gas flow. Furthermore, a complex pattern of delivery nozzles does not eliminate the non-uniformities caused by the radial flow on the exhaust (back) side of the substrate/chuck.

Aspects and embodiments of the present disclosure address these and other challenges of the modern device manufacturing technology by providing for systems and techniques that deploy a multichannel showerhead supporting delivery of the carrier gases and various carried substances and evacuation of said gases/substances from the same (e.g., top) side of the substrate. More specifically, the gas outlet ports of the disclosed showerheads can be interspersed with the exhaust inlet ports with both the gas outlet ports and the exhaust inlet ports supporting the carrier gas flow substantially normally (perpendicularly) to the surface of the substrate. Multiple sets of gas outlet/exhaust ports can be distributed around the bottom surface of the showerhead facing the substrate. The combination of the normal flow and same-side positioning of the ports minimizes (or substantially decreases) the radial flow of the carrier gas and, therefore, significantly reduces the non-uniformities of the delivered substances and/or reaction by-products compared with conventional showerheads.

Further advantages of the disclosed systems and techniques include maintaining a high degree of uniformity of concentrations of substances and by-products in the instances of a time-dependent gas flow, e.g., when delivery of the substances and/or carrier gas occurs over a certain period of time and evacuation of the by-products and/or residual substances occurs over a different period of times. The normal delivery and evacuation causes no (or little) radial flow and results in high-quality manufacturing products.

The disclosed embodiments pertain to a variety of manufacturing techniques that use processing chambers (that may include deposition chambers, etching chambers, and the like), such as chemical vapor deposition techniques (CVD), physical vapor deposition (PVD), plasma-enhanced CVD, plasma-enhanced PVD, sputter deposition, atomic layer deposition, combustion CVD, catalytic CVD, evaporation deposition, molecular-beam epitaxy techniques, and so on. Although the most significant practical impact of the disclosed embodiments may be expected to occur in techniques that use vacuum deposition chambers (e.g., ultrahigh vacuum CVD or PVD, low-pressure CVD, etc.), the same systems and methods can be utilized in atmospheric pressure deposition chambers for uniform delivery/evacuation of substances thereto/from.

A “wafer” or “substrate,” as used herein, refers to any substrate or material surface formed on a substrate upon which film processing is performed during a fabrication process. For example, a wafer surface on which processing can be performed includes any intrinsic (undoped) or doped materials such as silicon, silicon oxide, silicon nitride, strained silicon, silicon on insulator, silicon oxides with carbon, amorphous silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

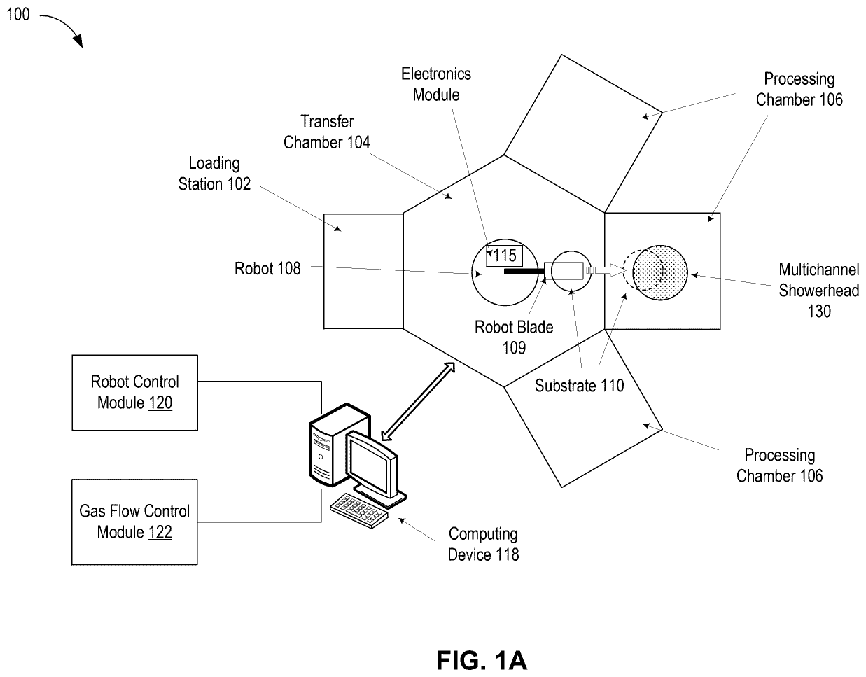

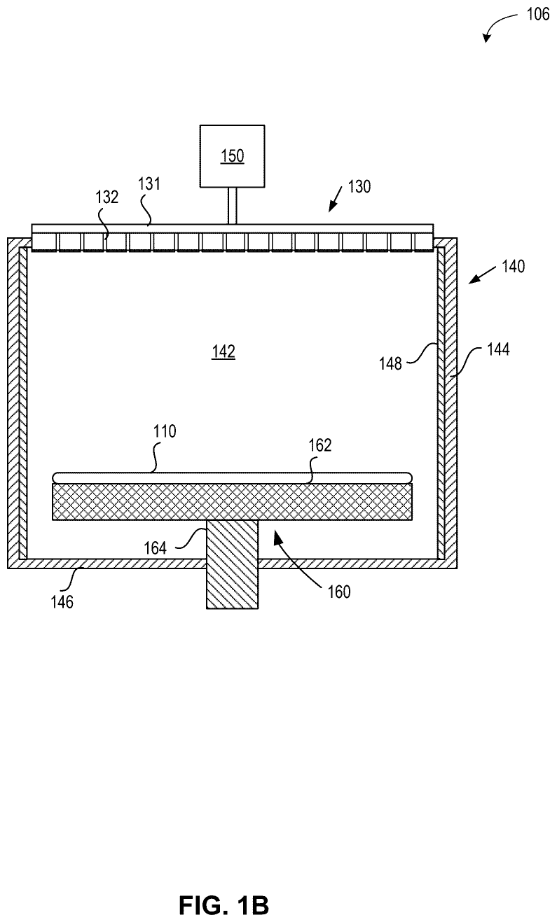

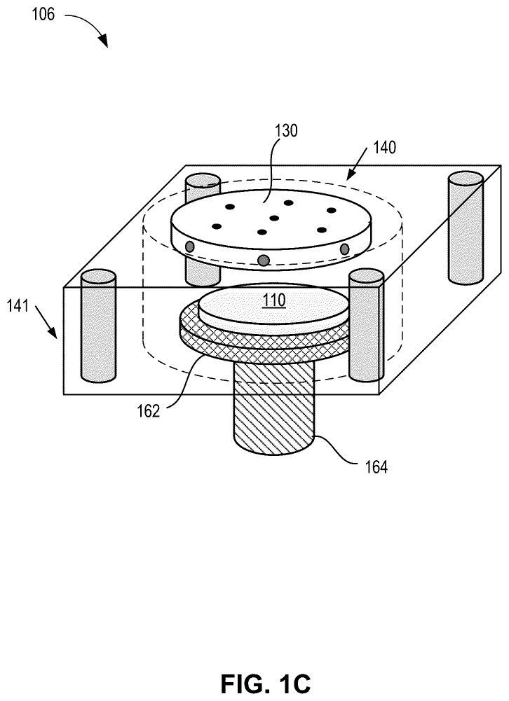

FIG. 1A illustrates an example manufacturing system 100 capable of deploying a multichannel showerhead with the same-side placement of delivery and exhaust ports, according to at least one embodiment. In one embodiment, the manufacturing system 100 includes a loading station 102, a transfer chamber 104, and one or more processing chambers 106. The processing chamber(s) 106 may be interfaced to the transfer chamber 104 via transfer ports (not shown). The number of processing chamber(s) associated with the transfer chamber 104 may vary (with three processing chambers indicated in FIG. 1A, as a way of example). The transfer chamber 104 may include a robot 108 with a robot blade 109 capable of transporting a substrate 110 into (and out of) any or some of the processing chambers 106. The transfer chamber 104 can be held under pressure (temperature) that is higher (or lower) than the atmospheric pressure (temperature). The robot blade 109 can include an extendable arm sufficient to move substrate 110 to a designated position inside processing chamber 106, e.g., under multichannel showerhead 130. The robot blade 109 may include an alignment device to properly align a notch, indent, hole (or some other feature) of substrate 110 relative to the robot blade 109. The robot blade 109 can carry substrate 110 into the processing chamber(s) 106 through a slit valve port (not shown). The processing chamber(s) 106 can contain processing gases, plasma, and/or various other particles used in deposition processes. A magnetic field can exist inside the processing chamber(s) 106. The inside of the processing chamber(s) 106 can be held at temperatures and pressures that are different from the temperature and pressure of the transfer chamber 104 and/or other processing chamber(s) 106.

A computing device 118 may control various operations of the manufacturing system 100. The computing device 118 may communicate with an electronics module 115 of the robot 108. In some embodiments, such communication may be performed wirelessly. Computing device 118 may include a robot control module 120 that controls operations of the robot 108 (including robot blade 109), e.g., retrieval of substrate 110 from loading station 102, bringing substrate 110 into transfer chamber 104 for degassing, pressure equalization, and/or the like, moving substrate 110 into one of the processing chamber(s) 106, placing substrate 110 onto a chuck (not shown) inside the processing chamber(s) 106, removing substrate 110 from the processing chamber(s) 106 following completion of one or more processing operations (e.g., deposition, etch, polishing, cleaning, and/or the like), transferring substrate 110 to loading station 102, and/or the like. Computing device 118 can further include a gas flow control module 122 that controls delivery of various substances (and carrier gases, if applicable) into the environment of processing chamber(s) 106, including starting and stopping a gas flow, starting and stopping an exhaust flow, controlling an amount and/or chemical composition of the gas flow, and/or the like.

FIG. 1B is a sectional view of a processing chamber 106 having a multichannel showerhead with the same-side placement of delivery and exhaust ports, according to at least one embodiment. The processing chamber 106 may be used for processes in which an environment having plasma processing conditions is provided. For example, the processing chamber 106 may be a chamber for a plasma etcher or plasma etch reactor, a plasma cleaner, plasma enhanced CVD, ALD, Etch or Epitaxy reactors, and so forth.

In one embodiment, the processing chamber 106 includes a chamber body 140 and multichannel showerhead 130 that enclose an interior volume 142. The multichannel showerhead 130 may include a showerhead base and a showerhead gas distribution plate. The chamber body 140 may be fabricated from aluminum, stainless steel, titanium, and/or any other suitable material. The chamber body 140 generally includes sidewalls 144 and a bottom plate 146. A coating layer 148 may be disposed adjacent to the sidewalls 144 to protect the chamber body 140.

The multichannel showerhead 130 can be supported by the sidewall 144 of the chamber body 140. The multichannel showerhead 130 can be opened to allow access to the interior volume 142 of the processing chamber 106 and can seal the processing chamber 106 while closed. A gas panel 150 may be coupled to the processing chamber 106 to provide process and/or cleaning gases to the interior volume 142 through the multichannel showerhead 130. Multichannel showerhead 130 may be deployed in conjunction with processing chambers used for etching and/or deposition of dielectric materials, conducting materials, semiconducting materials, and/or any other suitable materials. Multichannel showerhead 130 can include a gas distribution plate (GDP) 131 and multiple gas delivery channels 132 throughout the area of GDP 131 and can further include multiple gas exhaust channels (not shown in FIG. 1B for conciseness). In some embodiments, GDP 131 can be made from Si or SiC, or may be a ceramic such as Y₂O₃, Al₂O₃, Y₃Al₅O₁₂ (YAG), and so forth.

Examples of processing gases can may be used to process substrates in the processing chamber 106 include (but are not limited to) halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A heater assembly 160 can be disposed in the interior volume 142 of the processing chamber 106, e.g., below the multichannel showerhead 130. The heater assembly 160 can include a chuck (support) 162 that securely holds substrate 110 during processing. The chuck 162 can be attached to the end of a shaft 164 that is coupled to the chamber body 140 via a flange. The chuck 162, shaft 164 and the flange can be constructed of a heater material containing AlN, for example, an AlN ceramic. The chuck 162 can further include mesas (e.g., dimples or bumps). The chuck 162 can additionally include wires, for example, tungsten wires (not shown), embedded within the heater material of the chuck 162. In one embodiment, the chuck 162 can include metallic heater and sensor layers that are sandwiched between AlN ceramic layers. Such an assembly can be sintered in a high-temperature furnace to create a monolithic structure that includes a combination of heater circuits, sensor elements, ground planes, radio frequency grids and metallic and ceramic flow channels.

FIG. 1C is a perspective view of another processing chamber 106 having a multichannel showerhead with same-side placement of delivery and exhaust ports, according to at least one embodiment. As illustrated, chamber body 140 can have a cylindrical form enclosed in a rectangular housing 141. Multichannel showerhead 130 is disposed at the top portion of chamber body 140, e.g., directly above chuck 162. In some embodiments, chuck 162 can be an electrostatic chuck, e.g., a chuck holding substrate 110 using forces of electrostatic attraction. In some embodiments, chuck 162 can be a suction (vacuum) chuck, e.g., a chuck holding substrate 110 using suction action. In some embodiments, chuck 162 can hold substrate 110 using a mechanical action, e.g., forces exerted on substrate 110 by a suitable pattern of grooves, holes, and/or other features that securely hold substrate 110 in place. In some embodiments, chuck 162 can be raised and/or lowered by shaft 164 so that the distance from substrate 110 to multichannel showerhead 130 can be changed.

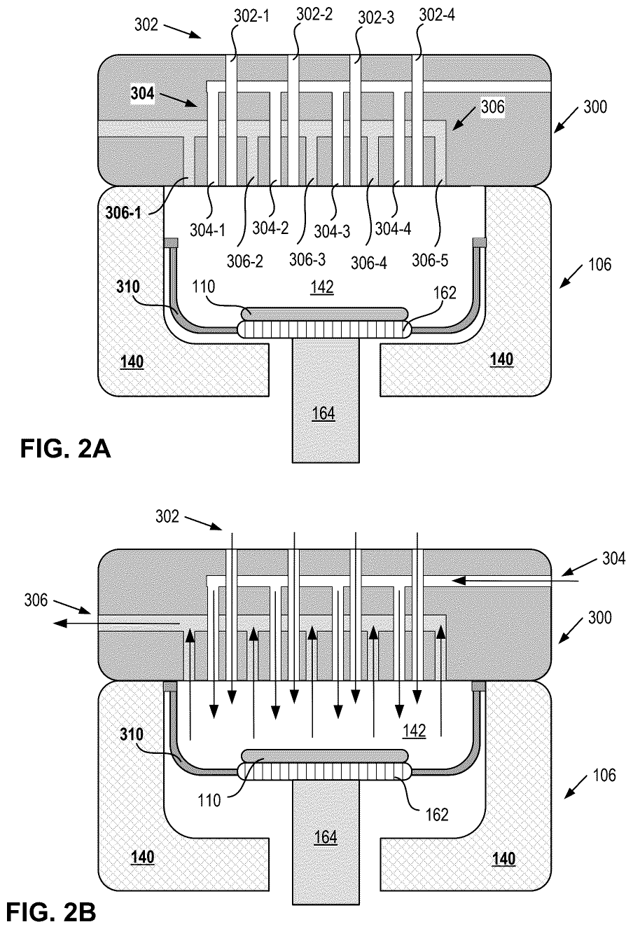

FIG. 2A-2B illustrate operations of an example processing chamber having a multichannel showerhead 300 with same-side placement of delivery and exhaust ports, according to at least one embodiment. Multichannel showerhead 300 can be the multichannel showerhead 130 of FIG. 1A-1C. Multichannel showerhead 300 can have one or more gas delivery (intake) channels and at least one gas exhaust channel. “Channel” should be understood as any interconnected system of pipes, tubes, conduits, and/or other suitable lines capable of transferring a distinct gas or a mixture of gases and/or other suitable materials, e.g., plasma, fluids, etc. A “channel” can include any number of inlet and outlet ports. For example, as illustrated in FIG. 2A, a first delivery channel 302 includes multiple vertical conduits 302-1, 302-2, 302-3, and 302-4 (connecting the corresponding inlet ports at the top surface of the showerhead to the outlet ports at the bottom surface of the showerhead) and allows delivery of a first set of substances to the interior volume 142 of processing chamber 106. A second delivery channel 304 includes horizontal and vertical conduits ending with outlet ports 304-1, 304-2, 304-3, and 304-4 and allows delivery of a second set of substances (which can be different from the first set of substances) to interior volume 142. As further illustrated in FIG. 2A, an exhaust channel 306 includes multiple exhausts inlet ports 306-1, 306-2, 306-3, 306-4, and 306-5 and allows evacuation of reaction by-products (and unspent amounts of the first set of substances and the second set of substances) from interior volume 142 of processing chamber 106. In some embodiments, chuck 162 supporting substrate 110 can be connected to a sealing flange 310 capable of sliding along the walls of the chamber body 140 while sealing the interior volume 142 form the outside environment. FIG. 2A illustrates an inactive stage of operations of the processing chamber 106 when no gas flows through the delivery/exhaust channels into/from the interior volume 142.

FIG. 2B illustrates an active stage of operations of processing chamber 106 with gas flowing through the delivery/exhaust channels into/from chamber body 140. As illustrated, the first delivery channel 302 delivers a first set of substances (which can include a first carrier gas) into the interior volume 142 while the second delivery channel 304 delivers a first set of substances (which include a second carrier gas) into the interior volume 142. The first set of substances and/or the second set of substances can facilitate any suitable processing operations on substrate 110. The exhaust channel 306 evacuates the processing by-products and any unspent volumes of the first set of substances and the second set of substances. As further illustrated in FIG. 2B, during the active stage, the combination of chuck 162 and substrate 110 can be elevated towards multichannel showerhead 300 by shaft 164. As chuck 162 is moved upwards, the sealing flange 310 slides along the chamber body 140 while keeping the interior volume 142 sealed form the outside environment.

In some embodiments, flange 310 can be deployed to ensure that interior volume 142 around substrate is separated symmetric (to ensure a higher degree of control of gas flow within interior volume 142) from the rest of the processing chamber 106, which can have one or more intrinsic asymmetries, e.g., presence of a wafer load/unload port on one side of the chamber. In some embodiments, flange 310 can be used when the exhaust channel is routed back through the chamber cavity (e.g., where outer port of the exhaust channel 306 is located inside the chamber cavity but outside the interior volume 142 defined by flange 310 (not explicitly shown in FIG. 2A-2B). In some embodiments, e.g., where the exhaust channel 306 is routed as shown in FIG. 2A-2B, flange 310 may be absent.

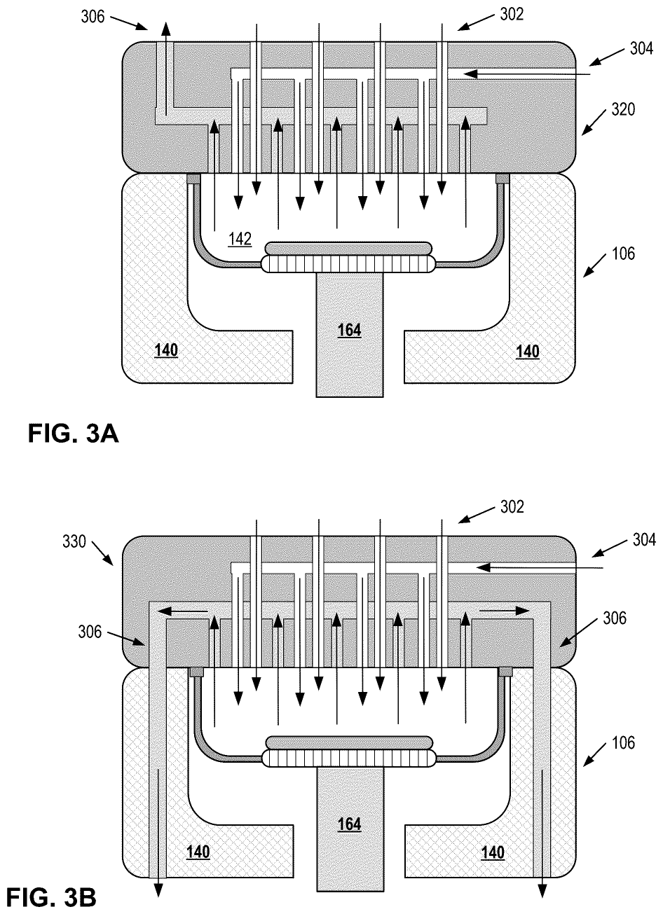

FIG. 3A-3B illustrate other possible configurations of a multichannel showerhead 300 with same-side placement of delivery and exhaust ports, according to at least one embodiment. FIG. 3A illustrates a multichannel showerhead 320 with same-side placement of delivery and exhaust ports and an exhaust removal through the top of the showerhead. As illustrated, the configurations of the first delivery channel 302 and the second delivery channel 304 are similar to those illustrated in the embodiments of FIG. 2A-2B, but the exhaust gas is removed through outlet port(s) of the exhaust channel 306 located at the top of the multichannel showerhead 320. FIG. 3B illustrates another multichannel showerhead 330 with same-side placement of delivery and exhaust ports and the exhaust gas removal through the bottom of the multichannel showerhead 330. As illustrated, te configurations of the first delivery channel 302 and the second delivery channel 304 are similar to those illustrated in the embodiments of FIG. 2A-2B and FIG. 3A, but the exhaust gas is removed through outlet port(s) of the exhaust channel 306 located at the bottom of the multichannel showerhead 330 and further through conduits in chamber body 140.

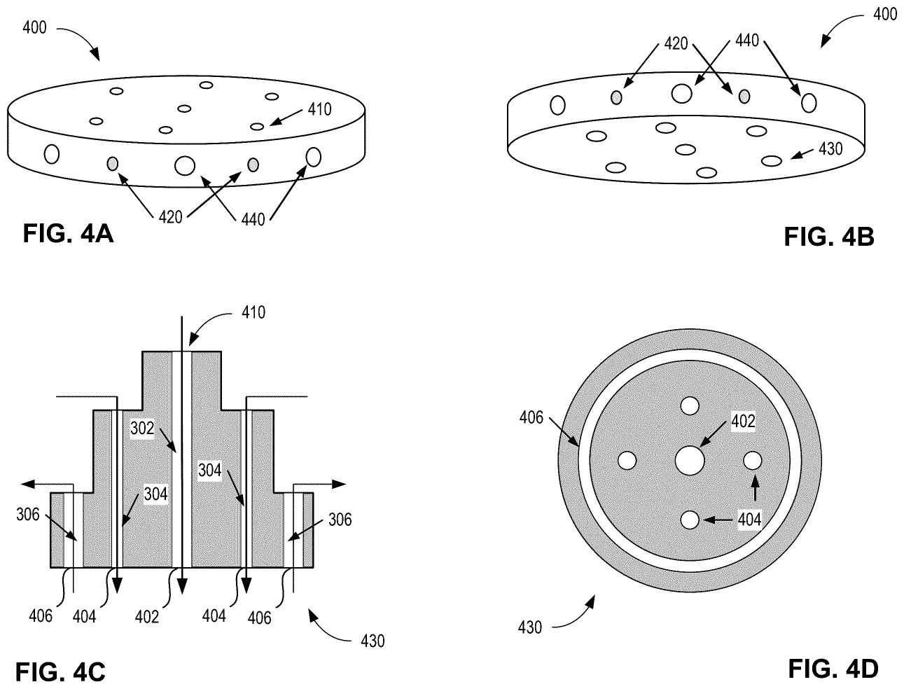

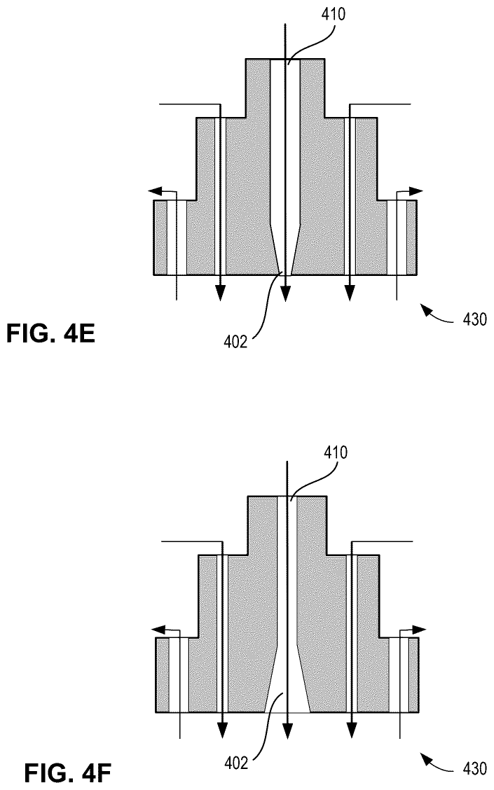

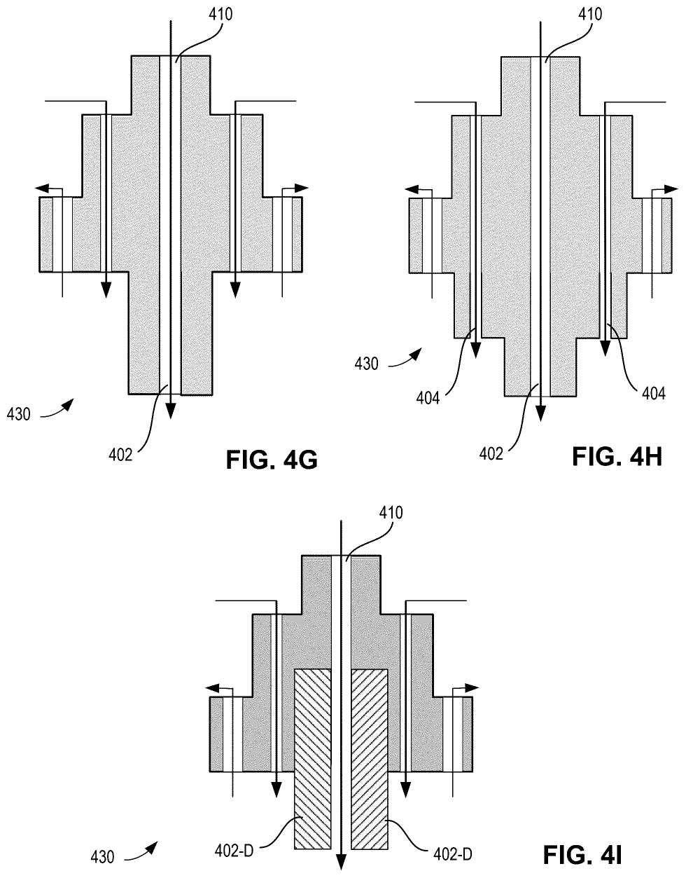

FIG. 4A-4I illustrate example multichannel showerheads with same-side placement of delivery and exhaust ports, according to at least one embodiment. FIG. 4A illustrates the perspective view of the top/side surface of the multichannel showerhead 400. FIG. 4B illustrates the perspective view of the bottom/side surface of the multichannel showerhead 400. The top surface of the multichannel showerhead 400 can include one or more inlet ports 410 of the first delivery channel for delivery of a first set of substances into a processing chamber. The edge surface of the multichannel showerhead 400 can include one or more inlet ports 420 of the second delivery channel for delivery of a second set of substances into the processing chamber. The edge surface can further include one or more exhaust outlet ports 440 of the exhaust channel that evacuates the processing by-products and unspent amounts of the first set of substances and the second set of substances from an interior volume (e.g., interior volume 142, with reference to FIG. 2A-3B) of the processing chamber. The bottom surface of the multichannel showerhead 400 can include one or more units 430 facing the inside environment of the processing chamber. FIG. 4C illustrates the cross-sectional view of an example unit 430 of the multichannel showerhead 400. FIG. 4D illustrates the bottom view of the example unit 430 of the multichannel showerhead 400. As illustrated in FIG. 4C, the unit 430 can include one or more outlet ports 402 of the first delivery channel 302, one or more outlet ports 404 of the second delivery channel 304, and one or more exhaust inlet ports 406 of the exhaust channel 306. As further illustrated, the gas flow in the first delivery channel 302 can be directed vertically, from the inlet port 410 of the first channel towards the outlet port 402 of the first channel. The gas flow in the second delivery channel 304 can initially be directed horizontally, e.g., with the gas flowing through the inlet port(s) 420 of the second channel before being redirected downward towards the outlet port(s) 404 of the second channel. The gas flow in the exhaust channel 306 can initially be directed upwards through exhaust inlet ports 406 before being redirected horizontally through the exhaust outlet ports 440. Connections between the inlet ports 420 and the outlet ports 404 (and, similarly, between the exhaust inlet ports 406 and the exhaust outlet ports 440) can be facilitated by a suitable fabric (network) of conduits (pipes, tubes, etc.) not explicitly shown in FIG. 4A-4I. FIG. 4D illustrates one example non-limiting arrangement of the unit 430 with a central outlet port 402 of the first channel, multiple (four are shown) outlet ports 404 of the second channel, and a circular exhaust inlet ports 406. FIG. 4E illustrates one example non-limiting arrangement of the unit 430 with a converging (tapered) outlet port 402 of the first channel. FIG. 4F illustrates one example non-limiting arrangement of the unit 430 with a diverging outlet port 402 of the first channel. FIG. 4G illustrates one example non-limiting arrangement of the unit 430 with an extended outlet port 402 of the first channel. FIG. 4H illustrates one example non-limiting arrangement of the unit 430 with an extended outlet port 402 of the first channel and extended outlet ports 404 of the second channel. FIG. 4I illustrates one example non-limiting arrangement of the unit 430 with an outlet port of the first channel outfitted with extended detachable nozzles 402-D.

It should be understood that the specific arrangements of channels and nozzles illustrated in FIG. 4A-4I is intended as an example and that multiple alternative arrangements are within the scope of the instant disclosure. Such alternative arrangements can differ by the number of units 430, the number of ports of each functionality within an individual unit 430 (e.g., in one embodiment, outlet port(s) 404 of the second channel can also be arranged into a cylindrical conduit), direction of flow, and/or the like. For example, in one embodiment, the first delivery channel 302 (or the second delivery channel 304) can be used as the exhaust channel 306 and vice versa.

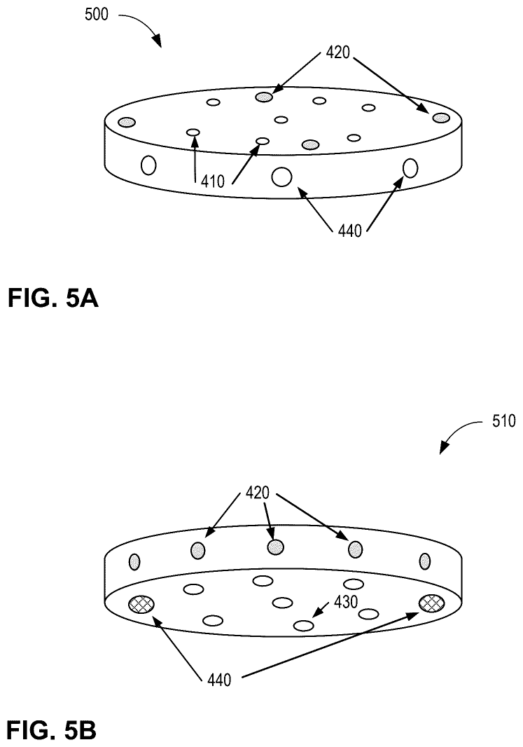

FIG. 5A-5B illustrate additional example multichannel showerheads with same-side placement of delivery and exhaust ports, according to at least one embodiment. More specifically, the inlet ports 410 of the first channel in FIG. 5A are distributed around the top surface of a multichannel showerhead 500 while the inlet ports 420 of the second channel in FIG. 5A are distributed around the edge of the top surface. In another embodiment of FIG. 5B, the inlet ports 420 of the second channel are distributed around the side surface of a multichannel showerhead 510 while the exhaust inlet ports (located within units 430) and the exhaust outlet ports 440 are located near the edges of the bottom surface of multichannel showerhead 510 (e.g., as also shown in FIG. 3B).

In some embodiments, the number of delivery channels in a multichannel showerhead can be one, three, four, and/or some other suitable number. In some embodiments, a multichannel showerhead can support more than one exhaust channel. In some embodiments, a gas flow in any of the delivery (or exhaust) channels can occur under chocked flow conditions when the gas velocity is equal to the sound velocity. In some embodiments, a multichannel showerhead can be use for delivery and evacuation of fluids or a combination of fluids and gases (e.g., delivery of fluid materials and evacuation of gases).

A multichannel showerhead can be implemented in a plastic material, a metal material, an alloy material, a composite material, and/or any combination thereof. Gas-facing surfaces of a multichannel showerhead can be coated with material resistant to the gases and/or various chemicals delivered via the multichannel showerhead. Manufacturing of a multichannel showerhead can be performed using three-dimensional (3D) printing, casting, forging, molding, and/or any other suitable techniques.

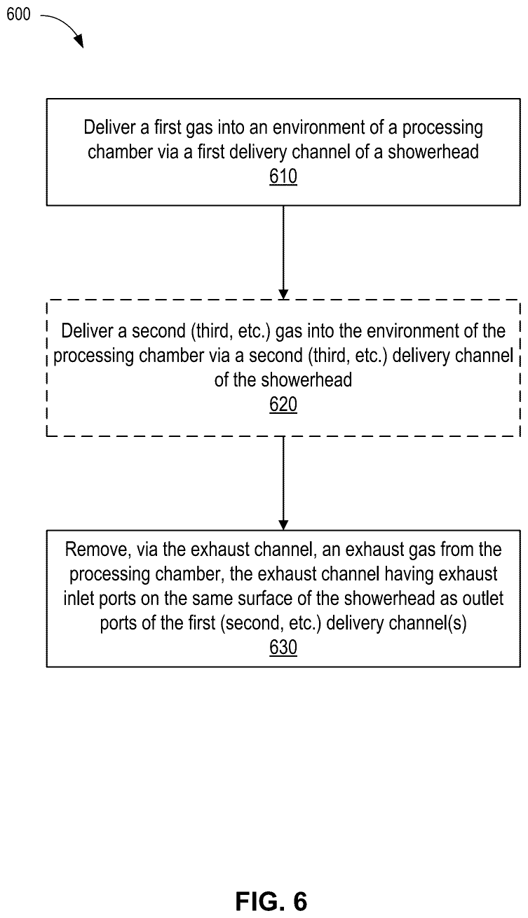

FIG. 6 is a flowchart illustrating an example method 600 of using a multichannel showerhead with same-side placement of delivery and exhaust ports in device manufacturing, in accordance with at least one embodiment. Method 600 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle substrates, e.g., moving substrates into and out of processing chambers. The transfer chamber can further be connected to a load-lock chamber (Front-End Interface) that can be coupled to one or more Front Opening Unified Pod carriers that hold bare substrates, processed substrates, partially processed substrates, and/or the like. Operations performed by the semiconductor manufacturing system, including any, some or all operations of method 600, can be performed responsive to instructions issued by a suitable computing device having a processing logic and memory (e.g., non-transitory computer-readable memory) to store the instructions.

Method 600 can include, at block 610, delivering a first gas into an environment of a processing chamber via a showerhead (e.g., gas showerhead) having a first surface, a second surface, and a side surface. The first gas can interact with a substrate located in the environment of the processing chamber. The showerhead can include at least a first delivery channel and an exhaust channel, but can also include a second (third, etc.) delivery channel(s). In some embodiments, the showerhead can include more than one exhaust channel. The first delivery channel can include one or more first inlet ports (e.g., inlet ports 410 in FIG. 4A-4C) through at least one of the first surface (e.g., the top surface of the showerhead) or the side surface. The one or more first inlet ports can be used to intake the first gas. The first delivery channel can further include a plurality of first outlet ports (e.g., outlet ports 402 in FIG. 4A-4C) through the second surface (e.g., the bottom surface of the showerhead) to output the first gas into the environment of the processing chamber. The exhaust channel can include a plurality of exhaust inlet ports (e.g., exhaust inlet ports 406 in FIG. 4A-4C) through the second surface to evacuate an exhaust gas from the environment of the processing chamber. The exhaust gas can include one or more products of an interaction of the first gas with the substrate. The exhaust channel can further include one or more exhaust outlet ports (e.g., exhaust outlet ports 440 in FIG. 4A-4C) through at least one of the first surface, the second surface, or the side surface to exhaust the exhaust gas from the showerhead.

In some embodiments, each first outlet port of the plurality of first outlet ports is configured to direct a flow of the first gas substantially perpendicularly to the substrate, e.g., such that an axis of the first outlet ports makes no more than 5 degrees (10 degrees, in some embodiments) with the direction normal (perpendicular) to the second surface. Similarly, each exhaust inlet port of the plurality of exhaust inlet ports may be configured to pass a flow of an exhaust gas into the showerhead substantially perpendicularly to the second surface, e.g., such that an axis of exhaust inlet ports makes no more than 5 degrees (10 degrees, in some embodiments) with the direction normal (perpendicular) to the second surface.

At block 620, method 600 can include delivering a second (third, etc.) gas into the environment of the processing chamber via (i) one or more second (third, etc.) inlet ports (e.g., inlet ports 420 in FIG. 4A-4C) through at least one of the first surface of the showerhead or the side surface of the showerhead, and (ii) a plurality of second (third, etc.) outlet ports (e.g., outlet ports 404 in FIG. 4A-4C) through the second surface of the showerhead to output the second (third, etc.) gas into the environment of the processing chamber. The exhaust gas can further include one or more products of a second (third, etc.) interaction of the second (third, etc.) gas with the substrate.

In some embodiments, the one or more first inlet ports can be connected to the plurality of first outlet ports via a plurality of first conduits. The one or more second inlet ports can be connected to the plurality of second outlet ports via a plurality of second conduits. Each of the plurality of second conduits can be isolated from each of the plurality of first conduits (such that the first gas and the second gas do not mix).

At block 630, method 600 can include removing, via the one or more exhaust outlet ports (e.g., exhaust outlet ports 440 in FIG. 4A-4C), the exhaust gas from the showerhead.

In some embodiments, the second surface can include a plurality of units (e.g., units 430 in FIG. 4C-4D). Each unit of the plurality of units can include an individual first outlet port (e.g., outlet port 402 in FIG. 4C-4D) of the plurality of first outlet ports, a subset of one or more second outlet ports (e.g., outlet ports 404 in FIG. 4C-4D) of the plurality of second outlet ports, and an individual exhaust inlet port (e.g., exhaust inlet port 406 in FIG. 4C-4D) of the plurality of exhaust inlet ports. In some embodiments, the individual first outlet port and the individual exhaust inlet port can be concentric to each other.

In some embodiments, e.g., as illustrated in FIG. 4A, the one or more first inlet ports can be disposed within the first surface, and the one or more second inlet ports can be disposed within the side surface. In some embodiments, e.g., as illustrated in FIG. 5A, the one or more first inlet ports and the one or more second inlet ports can be disposed within the first surface, and the one or more exhaust outlet ports can be disposed within the side surface.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

What is claimed is:

1. A gas showerhead comprising:
a first surface;
a second surface;
a side surface;
one or more delivery channels, each delivery channel comprising:
one or more inlet ports through at least one of the first surface or the side surface, and
a plurality of outlet ports through the second surface; and
an exhaust channel comprising:
a plurality of exhaust inlet ports through the second surface, and
one or more exhaust outlet ports through at least one of the first surface, the second surface, or the side surface.

2. The gas showerhead of claim 1, wherein each outlet port of the plurality of outlet ports is configured to output a flow of a gas substantially perpendicularly to the second surface, and wherein each exhaust inlet port of the plurality of exhaust inlet ports is configured to pass a flow of an exhaust gas substantially perpendicularly to the second surface.

3. The gas showerhead of claim 1, wherein the one or more delivery channels comprise:
a first delivery channel comprising a plurality of first conduits connecting the one or more inlet ports of the first delivery channel to the plurality of outlet ports of the first delivery channel; and
a second delivery channel comprising a plurality of second conduits connecting the one or more inlet ports of the second delivery channel to the plurality of outlet ports of the second delivery channel, wherein each of the plurality of second conduits is isolated from each of the plurality of first conduits.

4. The gas showerhead of claim 3, wherein the second surface comprises a plurality of units, each unit of the plurality of units comprising:
a first outlet port of the plurality of outlet ports of the first delivery channel,
one or more second outlet ports of the plurality of outlet ports of the second delivery channel; and
an exhaust inlet port of the plurality of exhaust inlet ports, wherein the first outlet port and the exhaust inlet port are concentric to each other.

5. The gas showerhead of claim 3, wherein the one or more inlet ports of the first delivery channel are disposed within the first surface, and wherein the one or more inlet ports of the second delivery channel are disposed within the side surface.

6. The gas showerhead of claim 3, wherein the one or more inlet ports of the first delivery channel and the one or more inlet ports of the second delivery channel are disposed within the first surface, and
wherein the one or more exhaust outlet ports are disposed within the side surface.

7. The gas showerhead of claim 1, wherein the gas showerhead is manufactured using three-dimensional (3D) printing.

8. A method comprising:
delivering a first gas into an environment of a processing chamber via a showerhead having a first surface, a second surface, and a side surface, wherein the first gas interacts with a substrate located in the environment of the processing chamber, and wherein the showerhead comprises:
a first delivery channel comprising:
one or more first inlet ports through at least one of the first surface or the side surface, the one or more first inlet ports to intake the first gas, and
a plurality of first outlet ports through the second surface to output the first gas into the environment of the processing chamber; and
an exhaust channel comprising:
a plurality of exhaust inlet ports through the second surface to evacuate an exhaust gas from the environment of the processing chamber, wherein the exhaust gas comprises one or more products of an interaction of the first gas with the substrate, and
one or more exhaust outlet ports through at least one of the first surface, the second surface, or the side surface to exhaust the exhaust gas from the showerhead; and
removing, via the one or more exhaust outlet ports, the exhaust gas from the showerhead.

9. The method of claim 8, wherein each first outlet port of the plurality of first outlet ports is configured to direct a flow of the first gas substantially perpendicularly to the substrate, and wherein each exhaust inlet port of the plurality of exhaust inlet ports is configured to pass a flow of an exhaust gas into the showerhead substantially perpendicularly to the second surface.

10. The method of claim 8, further comprising:
delivering a second gas into the environment of the processing chamber via:
one or more second inlet ports through at least one of the first surface of the showerhead or the side surface of the showerhead, and
a plurality of second outlet ports through the second surface of the showerhead to output the second gas into the environment of the processing chamber; and
wherein the exhaust gas further comprises one or more products of a second interaction of the second gas with the substrate.

11. The method of claim 10, wherein:
the one or more first inlet ports are connected to the plurality of first outlet ports via a plurality of first conduits; and
the one or more second inlet ports are connected to the plurality of second outlet ports via a plurality of second conduits, wherein each of the plurality of second conduits is isolated from each of the plurality of first conduits.

12. The method of claim 10, wherein the second surface comprises a plurality of units, each unit of the plurality of units comprising:
an individual first outlet port of the plurality of first outlet ports,
a subset of one or more second outlet ports of the plurality of second outlet ports; and
an individual exhaust inlet port of the plurality of exhaust inlet ports, wherein the individual first outlet port and the individual exhaust inlet port are concentric to each other.

13. The method of claim 10, wherein the one or more first inlet ports are disposed within the first surface, and wherein the one or more second inlet ports are disposed within the side surface.

14. The method of claim 10, wherein the one or more first inlet ports and the one or more second inlet ports are disposed within the first surface, and
wherein the one or more exhaust outlet ports are disposed within the side surface.

15. The method of claim 8, wherein the showerhead is manufactured using three-dimensional (3D) printing.

16. A semiconductor manufacturing system comprising:
a processing chamber comprising a substrate; and
a gas showerhead having a first surface, a second surface, and a side surface, the gas showerhead comprising:
one or more delivery channels, each delivery channel comprising:
one or more inlet ports through at least one of the first surface or the side surface, and
a plurality of outlet ports through the second surface; and
an exhaust channel comprising:
a plurality of exhaust inlet ports through the second surface, and
one or more exhaust outlet ports through at least one of the first surface, the second surface, or the side surface.

17. The semiconductor manufacturing system of claim 16, wherein the one or more delivery channels comprise:
a first delivery channel comprising a plurality of first conduits connecting the one or more inlet ports of the first delivery channel to the plurality of outlet ports of the first delivery channel; and
a second delivery channel comprising a plurality of second conduits connecting the one or more inlet ports of the second delivery channel to the plurality of outlet ports of the second delivery channel, wherein each of the plurality of second conduits is isolated from each of the plurality of first conduits.

18. The semiconductor manufacturing system of claim 17, wherein the second surface comprises a plurality of units, each unit of the plurality of units comprising:
a first outlet port of the plurality of outlet ports of the first delivery channel,
one or more second outlet ports of the plurality of outlet ports of the second delivery channel; and
an exhaust inlet port of the plurality of exhaust inlet ports, wherein the first outlet port and the exhaust inlet port are concentric to each other.

19. The semiconductor manufacturing system of claim 17, wherein the one or more inlet ports of the first delivery channel are disposed within the first surface, and wherein the one or more inlet ports of the second delivery channel are disposed within the side surface.

20. The semiconductor manufacturing system of claim 17, wherein the one or more inlet ports of the first delivery channel and the one or more inlet ports of the second delivery channel are disposed within the first surface, and
wherein the one or more exhaust outlet ports are disposed within the side surface.
